(19) United States
(12) Patent Application Publication
(10) Pub. No.: US 2026/0212592 A1
(43) Pub. Date: Jul. 23, 2026

(54) COMPUTER-IMPLEMENTED LIGHTING PLANNING OF AN INTERIOR ROOM

(71) Applicant: SYNTHETIC DIMENSION GMBH, Puch bei Hallein (AT)

(72) Inventors: Michael GADERMAYR, Oberalm (AT); Luca DEBIASI, Salzburg (AT); Christoph HOFER, Salzburg (AT); Martin HUBER, Pfarrwerfen (AT)

(73) Assignee: SYNTHETIC DIMENSION GMBH, Puch bei Hallein (AT)

(21) Appl. No.: 19/138,380

(22) PCT Filed: Dec. 23, 2022
(86) PCT No.: PCT/EP2022/087809

§ 371 Date: Jun. 12, 2025

(51) Int. Cl. G06T 15/50; G06F 30/13

(52) U.S. Cl. CPC G06T 15/506; G06F 30/13; G06T 2200/24; G06T 2210/04

(57) ABSTRACT

A computer-implemented method for lighting planning of an interior room is proposed. The method comprises obtaining scanning data indicative of one or more scans of at least a part of the interior room performed with a user device, computing, based on the scanning data, a 3D room model indicative of a 3D geometry of the interior room and at least one of a surface material of a surface and an object located in the room, computing, based on the 3D room model, at least one lighting measure indicative of a lighting characteristic in at least a part of the room based on simulating a lighting generated by one or more artificial light sources located within the room, and determining, based on the at least one lighting measure, whether the simulated lighting in the at least part of the room meets a predefined lighting specification indicative of a quality of the lighting in the at least part of the room.

### TECHNICAL FIELD

The present disclosure generally relates to the field of computer-implemented modeling of an interior room. In particular, the present disclosure relates to a computer-implemented method for lighting planning of or in an interior room and/or an interior environment. Further, the present disclosure relates to a computing device configured to perform steps of the method, a corresponding computer program instructing the computing device to carry out steps of the method, and to a computer-readable medium storing such computer program.

### TECHNICAL BACKGROUND

Adequate and appropriate lighting, also referred to as illumination, can be relevant for human beings in both professional and private life. For example, a correct or appropriate lighting in at least a part of an interior room may be relevant to fulfill certain tasks. Non limiting examples can include the illumination of a working area or workbench in a professional environment, such as an industrial building, an office or a hospital, and the illumination of a working area or dedicated area in a private environment, such as a garage or part of a kitchen. Particularly in professional environments, lighting may even be subject to regulatory requirements. For offices, for example, standards can be defined determining the required minimum illumination in certain room areas. Apart from that, an appropriate lighting in an interior room may affect or influence a comfort or mood of an individual or human being, or to create a particular atmosphere in the interior room.

To fulfill or meet certain criteria related to illumination or lighting of or in an interior room, computer-aided lightning planning based on 3D models can be applied. While such a 3D model can for example be determined based on modeling building information that may be available for new buildings, for existing buildings such a model is typically not available. Manual acquisition of a 3D room geometry and determination of a corresponding model may be required in such cases, which can be time-consuming, thereby costly and prone to measurement errors.

Further, beyond the light sources, various variables or parameters, such as room geometry, wall colors, surface materials, floor materials, and objects in the room, for example items of furniture, may potentially impact the lighting in indoor environments or interior rooms. Basic computations based on few parameters, such as a number of light sources and room sizes in square meters or number of light sources and basic geometry, such as length, width, height of a room, can be used as approximative models, but may be prone to errors. Generally, the real lighting conditions can hardly be reflected by such basic computations. Also, particularly complex geometries (e.g. L-shaped rooms) can show a large deviation to the real world, real lighting conditions and/or real physics. Moreover, a manual acquisition and definition of various parameters, such as for example room geometry, wall elements, doors, windows, wall colors, floor materials, ceiling color/material and/or the objects of a room, may be very time consuming, costly and prone to errors. In addition, the manual generation of a corresponding 3D model may either be highly time consuming or may be over-simplified. Therefore, for practical applications, usually a trade-off between accuracy and efficiency of the computer-aided lighting planning has to be made.

### SUMMARY

It may, therefore, be desirable to provide for an improved computer-implemented method and corresponding computing device for lighting planning of or in an interior room and/or an interior environment, for example allowing for an accurate and efficient lighting planning.

This is achieved by the subject matter of the independent claims, wherein further embodiments are incorporated in the dependent claims and the following description.

Aspects of the present disclosure relate to a computer-implemented method for lighting planning of or in an interior room and/or interior environment, to a computing device configured to perform steps of said method, to a corresponding computer program, and to a computer-readably medium, for example a non-transitory medium, storing such program. It is emphasized that any disclosure presented hereinabove and hereinbelow with reference to one aspect of the present disclosure equally applies to any other aspect of the present disclosure. Further, it is noted that any embodiment or example described with reference to one aspect of the present disclosure can be combined with any other embodiment or example described with reference to another aspect of the present disclosure.

An aspect of the present disclosure relates to a computer-implemented method for lighting planning of or in an interior room and/or an interior environment. Alternatively or additionally, the method may relate to a computer-implemented method of determining lighting conditions and/or an illumination of or in an interior room and/or interior environment. The method comprises:
obtaining scanning data indicative of one or more scans of at least a part of the interior room performed with a user device;
computing, based on the scanning data, a 3D room model indicative of a 3D geometry of the interior room and at least one of a surface material of a surface and an object located and/or arranged in the room;
computing, based on the 3D room model, at least one lighting measure indicative of a lighting characteristic in at least a part of the room based on simulating a lighting generated by one or more artificial light sources located and/or arranged within the room; and
determining, based on the at least one lighting measure, whether the simulated lighting in the at least part of the room meets a predefined lighting specification indicative of a quality of the lighting in the at least part of the room.

The computer-implemented method for lighting planning of the interior room disclosed herein may involve automated or computer-implemented lighting simulation utilizing at least one 3D room model generated or obtained from scanning data of the room acquired with a user device. These features synergistically interact, thereby allowing to improve both accuracy and efficiency of the overall process of lighting planning. In particular, a realistic representation of the interior room, one or more surface materials of one or more surfaces of the room and/or one or more objects located in the room may be provided by or included in the 3D room model that is computed based on the scanning data. Thus, the lighting, lighting conditions and/or illumination may be realistically simulated in the at least part of the room. Further, by computing the at least one lighting measure, the simulated lighting in the at least part of the room can be quantitatively and thus accurately evaluated with respect to the predefined lighting specification. Also, versatile, various and/or different criteria related to the quality of the simulated lighting can be taken into consideration or be reflected by the lighting specification. Hence, overall versatility of the lighting planning process may be increased, for example allowing to apply the proposed method to different environments, purposes and use cases both in professional and private environments.

The interior room, as used herein, may generally refer to a room in an interior environment, such as a building or house of any type and size. This can include an interior room in a professional building or environment, such as an industrial building, a factory, an office, a workplace, a hospital, a lab, or the like, as well as an interior room in a private environment, such as a kitchen, a living room, a bedroom, an office, or the like. The interior room may have a certain interior volume and geometry defined by one or more boundaries of the room, such as one or more walls arranged on one or more sides of the room, a ceiling arranged at a top of the room, and a floor arranged at a bottom. Directions and orientations, such as “top and bottom” may refer to directions and orientations in the Earth's gravity field. It is emphasized that an interior room envisaged in the present disclosure can include one or more open sides. Also, the interior room can have an arbitrary shape, volume, geometry and/or size.

The scanning data may be obtained and/or determined based on scanning at least a part of the interior room (also referred to as room herein) using the user device, for example by a user moving the user device through at least a part of the room and/or by positioning the user device at different positions in the room. The scanning data may be derived from sensor data acquired or captured with one or more sensors of the user device, such as one or more image sensors and/or depth sensors. For example, sensor data and/or scanning data may be obtained and/or captured at a plurality of different viewing angles or positions in the room during one or more scans of the room. Optionally, a plurality of sensor data may be aggregated to form the scanning data. Generally, a scan of the room or part thereof may refer to acquiring the scanning data at one or more positions in the room, for example at a plurality of positions along a particular trajectory the user device may be moved, e.g. by a user, through the room.

For example, the scanning data can include point cloud data or one or more point clouds, which optionally may be aggregated in one or more scans of the room using the user device to provide or generate the scanning data. Alternatively or additionally, the scanning data can include sensor data, for example raw sensor data, as directly acquired and/or recorded with one or more image sensors and/or depth sensors of the user device in one or more scans of the room. Accordingly, the scanning data may include image sensor data (also referred to as image data) and/or depth sensor data (also referred to as depth data), and/or the scanning data may be derived from any one or more of such data. Generally, the scanning data can refer to data of any type and format, which data may include optical and/or geometrical 2D and/or 3D information about the interior room, such as lossless image data, compressed image data, lossy image data, pixel data, point cloud data, or any other data.

In the context of the present disclosure the user device may refer to a computing device including a processing circuitry with one or more processors for data processing. The user device may refer to a portable or mobile device, such as a smartphone, a smart device, a tablet or notebook. Alternatively, the user device may refer to a stationary computing device, such as a personal computer or the like.

The user device may comprise one or more sensors, for example one or more cameras with one or more image sensors, for acquiring image sensor data and/or for determining the scanning data. Alternatively or additionally, the user device may comprise one or more depth sensors for acquiring and/or determining the scanning data. For example, the user device may comprise a LIDAR sensor and/or stereo camera. Using a depth sensor to acquire or determine the scanning data may particularly allow to precisely determine or compute geometrical parameters of the interior room and/or one or more objects arranged or located therein, such as dimensions of the interior room or one or more boundaries thereof. Hence, using depth sensor data can further increase a quality and precision of the computed 3D model of the interior room.

The user device may further comprise a communication circuitry for communicatively coupling the user device to a computing device, such as another user device, a portable user device, a smartphone, a tablet, a server, a stationary computing device and/or a cloud computing network. It should be noted that some or all of the steps of the method described herein may be performed by one or both the user device and a computing device communicatively couplable to the user device and remote from the user device, such as another user device, a portable user device, a smartphone, a tablet, a server, a stationary computing device and/or a cloud computing network.

For example, the scanning data may be acquired at the user device and transmitted to the computing device, and the computing device may compute the 3D room model, simulate the lighting, compute the lighting measure and determine compliance of the simulated lighting with the predefined lighting measure.

Alternatively or additionally, some or all of these steps of computing the 3D room model, simulating the lighting, computing the lighting measure and determining compliance of the simulated lighting with the predefined lighting measure may be performed at the user device. Accordingly, the scanning data may be stored at the user device and/or at the computing device, and processed by any one or both of these devices.

In an example, obtaining the scanning data may comprise retrieving the scanning data from a data storage of the user device and/or a data storage of the computing device communicatively couplable to the user device. The scanning data may be accessed at the respective data storage of the user device and/or computing device. Optionally, obtaining the scanning data may include transmitting the scanning data or data related thereto from the user device to the computing device.

In yet another example, obtaining the scanning data may include acquiring the scanning data with at least one camera, at least one image sensor, and/or at least one depth sensor of the user device. For example, the scanning data of one or more scans may be acquired by moving the user device along one or more trajectories in the room, thereby acquiring sensor data at different positions and/or viewing angles, which may be combined, aggregated and/or merged to provide the scanning data.

According to an embodiment, the scanning data include point cloud data (or one or more point clouds) that includes a plurality of data points or data elements, each data point or element being associated with one or more spatial coordinates within the room. Therein, the point cloud data or scanning data may refer to two-dimensional (2D) point cloud data with a plurality of data points or elements in two spatial directions. Alternatively, the point cloud data or scanning data may refer to three-dimensional (3D) point cloud data with a plurality of data points or elements in three spatial directions.

Generally, the point cloud data and/or scanning data as referred to herein may denote a set of data points or data elements, which may be representative, indicative and/or descriptive of a geometry of the interior room, a geometry of one or more objects arranged, as well as positional information about the relative orientation and/or position of several objects with respect to one another and with respect to one or more particular spatial coordinates (e.g. reference points) of one or more boundaries of the room.

The 3D room model may be computed, for example by the user device and/or the computing device, based on analyzing the scanning data and reconstructing at least a part of the geometry of the room. In particular, one or more boundaries of the room, for example one or more walls, a ceiling and/or a floor, and their relative positions and/or orientations may be defined in the 3D room model. In addition, at least one of a surface material of a surface of the interior room and an object arranged in the room can be represented, modelled and/or included in the 3D room model. In particular, the 3D room model may be indicative of a plurality of surface materials of a plurality of surfaces in the room. Alternatively or additionally, the 3D room model may be indicative of a plurality of objects arranged in the room. Generally, the 3D room model, as used herein, may refer to a geometrical representation of the interior room and may further define one or more parameters or aspects relevant for, associated with and/or potentially influencing the lighting in the at least part of the room, including the description of at least one of a surface material of a surface in the room and/or a description of at least one object located in the room.

An object arranged in the room may, in the context of the present disclosure, refer to any type of object or structure positioned at arbitrary position in the room. For example, an object arranged in the interior room may be associated with, refer to and/or correspond to a fixedly installed object, such as a door, a window, or other installation in the room. Alternatively or additionally, an object in the room may be movable and/or displaceable. Non-limiting example of such objects can include a table, a desk, a cabinet, a bed, a couch, a chair, or any other item of furniture, item of use and/or item of decoration arranged in the room. One or more parameters descriptive of the object, for example descriptive of a geometry, a shape, a volume, a surface material, a color, and/or a size, may be included or contained in the 3D room model of the interior room.

According to an embodiment, computing, based on the 3D room model, the at least one lighting measure may include calculating the at least one lighting measure at the user device and/or at the computing device. Therein, the lighting may be simulated at the computing device and/or at the user device based on applying one or more simulation models to the 3D room model to simulate light emission by one or more artificial light sources located in the room, and to calculate the at least one lighting measure based on the simulated lighting or light emission by the one or more artificial light sources. Also a plurality of lighting measures may be determined.

Generally, the at least one lighting measure may refer to a numerical measure indicative and/or descriptive of one or more characteristics of the lighting (or lighting characteristics) that are expected based on the simulation of the lighting. Generally, a lighting characteristic, and hence also a lighting measure, may reflect or be associated with a physical property of the simulated lighting or simulated light in the room. Alternatively or additionally, a lighting characteristic and/or lighting measure may reflect or be associated with a human-perceptible effect the light may have on a typical or average human being or individual.

Further, as used herein, the predefined lighting specification indicative of the quality of the lighting may refer to or include a definition of one or more particular lighting characteristics, against which the simulated lighting and/or the at least one lighting measure can be evaluated. For instance, the predefined lighting specification may define one or more lighting characteristics and one or more values, for example threshold values, associated therewith. Accordingly, the predefined lighting specification may reflect or include one or more quality or lighting criteria for evaluating the simulated lighting and/or the computed at least one lighting measure. This may allow to apply various different criteria in the lighting planning, and hence may allow to apply the lighting planning described herein to various different use cases and applications both in professional and private environments.

Also, it is noted that the predefined lighting specification may be provided and/or adapted by means of a user input at the user device. For instance, a user may provide a user input related to one or more lighting criteria, such as a particular threshold value for the one or more lighting criteria, which may be used by the user device and/or computing device to generate the predefined lighting specification. Alternatively or additionally, several lighting specifications may be available at the user device and the user may select one of the available lighting specifications as the predefined lighting specification. Also, different lighting specifications may be applied to different areas of the room.

According to an embodiment, determining, based on the at least one lighting measure, whether the simulated lighting in the at least part of the room meets the predefined lighting specification includes evaluating the computed at least one lighting measure against or with respect to the predefined lighting specification. In particular, one or more lighting measures can be determined and analyzed with respect to one or more lighting specifications.

According to an embodiment, the at least one lighting measure is indicative of one or more of a light intensity, a light distribution, a homogeneity of the lighting, a color of the lighting, a color spectrum of the lighting, a color temperature of the lighting an energy consumption of the one or more artificial light sources, a human-perceptible atmosphere generated by the lighting in the room, and a degree of comfort on an individual in the room resulting from the lighting. Alternatively or additionally, simulating the lighting may include computing, at the user device and/or the computing device, one or more of a light intensity, a light distribution, a homogeneity of the lighting, a color of the lighting, a color spectrum of the lighting, a color temperature of the lighting an energy consumption of the one or more artificial light sources, a human-perceptible atmosphere generated by the lighting in the room, and a degree of comfort on an individual in the room resulting from the lighting. One or more of the aforementioned lighting measures may be determined based on simulating the lighting.

It should be noted that a lighting measure can be computed for a single position in the room or for a plurality of positions. For example, an average lighting measure may be computed for a particular area or volume in the at least part of the room or for the entire part of the room considered. Alternatively or additionally, a plurality of different lighting measures may be determined, for example at the same or at different positions in the room (or averaged over certain areas or the entire part of the room considered). Accordingly, it may also be determined whether the predefined lighting specification is met by the simulated lighting at one or a plurality of different positions in the interior room.

According to an embodiment, the predefined lighting specification is defined by one or more lighting criteria indicative of one or more of a light intensity threshold, a minimum light intensity, a maximum light intensity, a predefined light distribution, a threshold for a homogeneity of the lighting, a predefined color of the lighting, a predefined color spectrum of the lighting, a predefined color temperature of the lighting, a threshold for an energy consumption of the one or more artificial light sources, a predefined human-perceptible atmosphere generated by the lighting in the room, and a predefined degree of comfort on an individual in the room resulting from the lighting. Accordingly, a lighting criterion defined by the predefined lighting specification may refer to a particular value, for example a threshold value, of a particular lighting measure or lighting characteristic associated therewith.

Alternatively or additionally, determining whether the predefined lighting specification is met by the simulated lighting and/or the computed at least one lighting measure may include evaluating, at the user device and/or the computing device, the one or more determined lighting measures against one or more lighting criteria indicative of one or more of a light intensity threshold, a minimum light intensity, a maximum light intensity, a predefined light distribution, a threshold for a homogeneity of the lighting, a predefined color of the lighting, a predefined color spectrum of the lighting, a predefined color temperature of the lighting, a threshold for an energy consumption of the one or more artificial light sources, a predefined human-perceptible atmosphere generated by the lighting in the room, and a predefined degree of comfort on an individual in the room resulting from the lighting.

According to an embodiment, determining whether the simulated lighting in the at least part of the room meets the predefined lighting specification includes comparing the at least one lighting measure to one or more lighting criteria associated with and/or defined by the predefined lighting specification. For example, one or more lighting measures may be computed based on simulating the lighting and compared to one or more lighting criteria defined in one or more lighting specifications.

Optionally, an effect or impact the simulated lighting may expectedly have on an individual or human being, such as a human-perceptible atmosphere generated by the lighting in the room, a mood generated by the lighting, and/or the degree of comfort on an individual in the room resulting from the lighting, may be determined based on a continuous variable or lighting measure on an arbitrary scale. For instance, the effect or impact the simulated lighting may expectedly have on an individual or human being may be determined based on computing one or more further lighting measures. As an example, a particular color or color temperature may be known to have a particular impact on a human being. Hence, by determining the color or color temperature of the simulated lighting, also the effect of the lighting on an individual may be determined by computing a corresponding lighting measure for this effect and by comparing the computed lighting measure to a corresponding lighting criterion contained in the lighting specification.

According to an embodiment, the method further comprises providing, at a user interface of the user device, information related to the computed at least lighting measure and/or related to a comparison of the at least one lighting measure to one or more lighting criteria associated with and/or defined by the predefined lighting specification. This may optionally include transmitting the information or corresponding data from the computing device to the user device. Further optionally, the information may be visualized at the user interface. Alternatively or additionally, the computed 3D room model and/or at least a part of the scanning data may be displayed and/or visualized at a user interface of the user device.

For instance, the value of the computed at least one lighting measure may be visualized or provided at the user interface, optionally along with the computed 3D room model, a 2D floorplan derived from the 3D room model, a 2D slice of the 3D room model, and/or at least a part of the scanning data. Alternatively or additionally, one or more lighting measures may be reflected in a 2D or 3D overlay, such as a heat map, a color overlay or the like, and visualized at the user interface, for example based on displaying the overlay at the corresponding part or section of the computed 3D room model, a 2D slice thereof and/or a 2D floorplan derived therefrom.

Alternatively or additionally, the result of the comparison of the at least one lighting measure to one or more lighting criteria associated with and/or defined by the predefined lighting specification may be visualized, for example by providing a corresponding notification or indication at the user interface.

Optionally, contextual information of the lighting measure and its determination, such as results or characteristics of the simulation of the lighting, may be provided and/or visualized at the user interface. Further optionally, also information related to the predefined lighting specification and/or one or more lighting criteria defined therein may be visualized.

In an embodiment, the method may further comprise determining one or more regions or positions in the room, where the simulated lighting meets the predefined lighting specification, and optionally providing information related to the determined one or more regions or positions to the user device. For instance, the one or more positions or regions may be marked or highlighted in the 3D room model, a 2D slice thereof and/or a 2D floorplan derived therefrom, which may be displayed at the user interface of the user device. Alternatively or additionally, the method may further comprise determining one or more further regions or further positions in the room, where the simulated lighting does not meet the predefined lighting specification, and optionally providing information related to the determined one or more further regions or further positions to the user device. For instance, the one or more further positions or further regions may be marked or highlighted in the 3D room model, a 2D slice thereof and/or a 2D floorplan derived therefrom, which may be displayed at the user interface of the user device. Hence, it may be marked or flagged in the 3D room model and/or a 2D floorplan where or at which positions the lighting specification is fulfilled and where or at which positions not. This may allow to provide intuitive, comprehensive, qualtitative as well as quantitative feedback on the simulated lighting and whether the lighting specification is met to the user.

According to an embodiment, the method further comprises generating a conclusion as to whether the at least one lighting measure meets one or more lighting criteria associated with and/or defined by the predefined lighting specification. Optionally, information indicative of the generated conclusion may be provided at a user interface of the user device. This may include visualizing a result of the conclusion at the user interface of the user device. For instance, the conclusion may be generated at the computing device and the corresponding information or data may be transmitted to the computing device.

A conclusion as to whether the at least one lighting measure meets one or more lighting criteria associated with and/or defined by the predefined lighting specification may be determined for a single position, for multiple positions or regions in the room, and/or for the entire room. For instance, a conclusion may be reflected in a binary value, which may optionally be associated with one or more positions or regions in the room. Optionally, the binary values related to the position or region-specific conclusion may be mapped to corresponding positions or regions of the 3D room model and/or a 2D floorplan derived therefrom. Further optionally, the binary values related to the position or region-specific conclusion may be visualized at the user interface of the user device, for example as overlay on the 3D room model and/or the 2D floorplan.

According to an embodiment, computing the 3D room model indicative of the surface material comprises assigning one or more of a bidirectional reflectance function, a bidirectional texture function, a light reflectance value, an RGB reflectance vector, a multi-spectral reflectance vector, and a physically based rendering material model to one or more of a single point, a region, a surface and an object in the room. Alternatively or additionally, a surface material of a surface may be modelled and/or defined in the 3D room model based on one or more of a bidirectional reflectance function, a bidirectional texture function, a light reflectance value, an RGB reflectance vector, a multi-spectral reflectance vector, and a physically based rendering material model. One or more of these parameters may allow to accurately reflect the influence of the surface material on the lighting, and for example consider one or more of these parameters in the simulation of the lighting based on the computed 3D room model. Hence, the interior room may be realistically modelled in 3D room model to allow for an accurate lighting planning.

According to an embodiment, computing the 3D room model includes reconstructing a parametric 3D model indicative of the 3D geometry of the interior room based on representing one or more walls of the room by one or more base elements of predefined geometry and/or shape. Optionally, one or more objects arranged in the room may be represented by a corresponding parametric model for the object, which may be included in the 3D room model.

According to an embodiment, computing the 3D room model includes determining and/or approximating a geometry of the room based on representing at least one portion of the scanning data, for example point cloud data or a point cloud included therein, with one or more base elements having a predefined geometry and/or shape. For instance, at least a part of a point cloud included in the scanning data may be supplemented, substituted and/or replaced by one or more base elements in order to represent the at least one portion of the point cloud.

In an exemplary embodiment, each of the base elements, respectively the one or more base elements, may correspond to, be associated with and/or include a parametric model of predefined geometry and/or shape.

In a non-limiting example, each base element, respectively the one or more base elements, may correspond to, be associated with, and/or include a parametric model for and/or representative of one or more of a plane, a surface, an area, a planar surface, a spherical surface, a cylindrical surface, a conical surface, a curved surface, a polygonal surface, a circle, a circle section, an elliptical surface, a straight line, an arc, a circular arc, and a triangular surface. Accordingly, a base element may be associated with and/or represent a basic geometrical object of predefined basic geometry.

According to an embodiment, the one or more base elements have a two-dimensional or three-dimensional geometry. It is noted that also a plurality of base elements may be selected, wherein at least one may have a two-dimensional and at least a further one may have a three-dimensional geometry to represent and/or approximate the room geometry.

In an example, computing the 3D room model and/or approximating the at least part of the point cloud of the scanning data with a plurality of base elements may include selecting a plurality of base elements of same and/or different type, and calculating one or more spatial coordinates, and optionally further parameters for each base element, such that a number of data points or elements of the point cloud being arranged on or close to a surface of one or more of the base elements may be maximized. Accordingly, the one or more base elements may be fitted, e.g. based on adjusting one or more parameters of the one or more base elements, to points or elements of the point cloud of the scanning data, such that the sum or set of base elements forms an outer contour and/or surface that substantially or optimally resembles the geometry of the room. Hence, by determining the base elements, the room geometry can be reliably and efficiently be computed and/or approximated. Also, approximating the room geometry with one or more base elements, which may have basic or simple geometry, may allow to reduce a data volume for further processing and hence can speed-up the reconstruction process and overall process of lighting planning.

According to an embodiment, the 3D room model is computed based on representing one or more boundaries of the room with the one or more base elements. For instance, at least a part of a point cloud included in the scanning data, which refers to or includes said one or more boundaries, may be supplemented and/or replaced by one or more base elements in order to represent said one or more boundaries of the room by the one or more base elements. For instance, representing the at least one portion of the point cloud with the one or more base elements may include substituting and/or replacing the at least one portion of the point cloud with the one or more base elements.

In a further example, computing the 3D room model may include representing at least a portion of the scanning data, for example a portion of a point cloud included in the scanning data, by one or more objects arranged in the room. This may optionally include retrieving object data related to the one or more objects from a database, and substituting and/or replacing the at least one portion of the scanning data and/or point cloud with the one or more objects based to generate the 3D room model. For instance, one or more parametric models, e.g. parameterizing size, geometry, type, color, surface material and/or other data associated with one or more objects can be retrieved from the database.

According to an embodiment, computing the 3D room model, e.g. representing the at least one portion of the scanning data or a point cloud with the one or more base elements, includes adjusting and/or altering a size of the one or more base elements. For instance, each of the base elements may correspond to, be associated with and/or include a parametric model of predefined geometry and/or shape with one or more paramterizable and/or adjustable parameters. Therein, the size of a base element may be adjusted and/or altered based on adjusting and/or altering the one or more parameters of the respective parametric model of the base element. Also one or more of an expansion and/or dimension of a base element in one or more spatial directions may be adjusted based on adjusting one or more parameters of the corresponding parametric model.

According to an embodiment, the method may further comprise adjusting a size, dimension, and/or expansion of the one or more base elements based on parameterizing the one or more base elements in accordance with a spatial arrangement of the least one portion of the scanning data or point cloud to be represented by the one or more base elements.

According to an embodiment, computing the 3D room model, e.g. representing the at least one portion of the scanning data or point cloud with the one or more base elements, includes determining one or more of a size, a position, and an orientation of the one or more base elements. In particular, one or more parameters of one or more parametric models associated with the one or more base elements may be determined, such that a number of points of the point cloud being arranged at or near a surface of the one or more base elements is maximized.

According to an embodiment, the method further comprises adjusting a size, dimension, and/or expansion of the one or more base elements based on parameterizing the one or more base elements in accordance with a spatial arrangement of the least one portion of the scanning data or point cloud to be represented by the one or more base elements.

According to an embodiment, the 3D room model is computed and/or the geometry of the room is determined based on representing boundaries of the room with a spatial arrangement of a plurality of base elements. For instance, a plurality of base elements may be selected, adjusted in size, and arranged relative to each other to resemble the room geometry as indicated by the data points of the scanning data or point cloud.

By way of example, the spatial arrangement of the base elements may refer to a composition or sum of the base elements having certain geometries and shapes and being arranged relative to one another, such that the surface and/or outer contour of the arrangement of base elements is preferably congruent with a maximum number of points of the point cloud. Therein, the arrangement of base elements, the selected base elements, and/or the parameters of one or more parametric models of the base elements may be adapted or changed in an iterative process to identify the arrangement of base elements with the maximum number of points of the point cloud of the scanning data lying at or near the surface of the arrangement of base elements. Said arrangement of base elements may then be selected for further processing or modeling the interior room in the 3D room model.

According to an embodiment, the method further comprises optimizing the spatial arrangement of the plurality of base elements based on minimizing a number of base elements utilized for representing all boundaries of the room. For instance, one or more base elements may be iteratively replaced and/or removed from a set of selected base elements to determine the spatial arrangement requiring a minimum number of base elements to accurately represent the one or more boundaries of the room. This may allow to further reduce a processing burden for subsequent tasks of modeling the interior room based on or using the spatial arrangement of base elements.

According to an embodiment, the scanning data includes a point cloud (or corresponding point cloud data), which may be a three-dimensional point cloud, wherein the method may further comprise generating a two-dimensional point cloud based on projecting the at least one portion of the three-dimensional point cloud onto a two-dimensional plane, preferably a horizontal two-dimensional plane through the at least part of the point cloud. For example, the method may comprise converting the three-dimensional point cloud of the scanning data into a two-dimensional point cloud or corresponding 2D point cloud data. Alternatively or additionally, determining the geometry of the room and/or computing the 3D room model may include generating and/or creating a two-dimensional projection of the at least one portion of the point cloud. Alternatively or additionally, a planar section or cross-section through a 3D point cloud may be used to generate a 2D point cloud. In particular, a plurality of projections of a 3D point cloud and/or a plurality of 2D point clouds may be generated.

A two-dimensional point-cloud projection or cross-section through a three-dimensional point cloud may particularly allow to determine the layout or floorplan of the room in the 2D plane defined by the 2D point cloud or the projection. Also, a plurality of 2D point cloud projections or cross-sections in planes having different heights above a ceiling, floor or other wall of the room may allow to determine and/or detect tilted boundaries, as well as a tilting angle of such boundaries of the room, as is for example the case with mansards or otherwise tilted walls or boundaries. Also curved and/or curvilinear sections of the room and/or one or more boundaries may be reliably determined based on one or more projections of the 3D point cloud into a 2D plane traversing the room.

According to an embodiment, computing the 3D room model includes retrieving object data related to one or more objects located in the room and/or material data related to one or more (surface) materials of one or more surfaces in the room from a database. The object data may relate to one or more parametric models modelling one or more objects. Alternatively or additionally, the material data may include or define one or more surface materials of one or more surfaces in the room and/or of an object arranged in the room. Therein, a surface material may be defined in the material data based on one or more of a bidirectional reflectance function, a bidirectional texture function, a light reflectance value, an RGB reflectance vector, a multi-spectral reflectance vector, and a physically based rendering material model.

The object data may include a parametric model for an object, which may define or be parametrizable in one or more parameters of the object, such as geometry, size, shape, color, type, and surface material of the object. As noted above, a surface material may be defined in the object data (and/or material data) based on one or more of a bidirectional reflectance function, a bidirectional texture function, a light reflectance value, an RGB reflectance vector, a multi-spectral reflectance vector, and a physically based rendering material model. The parametric models for one or more objects may be adjusted to reconstruct the one or more objects in the scanning data, and the corresponding one or more parametrized object models may be included in the 3D room model.

Alternatively or additionally, one or more surface materials of one or more surfaces in the room and/or of objects may be resembled or represented in the computed 3D room model based on assigning corresponding material data to the one or more surfaces and/or objects. For instance, one or more of a bidirectional reflectance function, a bidirectional texture function, a light reflectance value, an RGB reflectance vector, a multi-spectral reflectance vector, and a physically based rendering material model may be assigned to one or more surfaces.

For instance, surfaces may be detected in the scanning data and analyzed based on estimating one or more of a bidirectional reflectance function, a bidirectional texture function, a light reflectance value, an RGB reflectance vector, a multi-spectral reflectance vector. Similar or identical values at different positions may indicate the same surface or a homogenous surface in the room, which may be assigned the same or similar material data.

According to an embodiment, the 3D room model is a parametric 3D model indicative of one or more materials of one or more surfaces in the room, one or more light sources, one or more windows, one or more doors, one or more walls, one or more objects arranged in the room, and/or one or more items of furniture arranged in the room. For example, one or more homogenous surfaces may be detected based on analyzing the scanning data, and corresponding material data may be assigned to the surface. This may particularly allow to accurately reflect the properties of the surfaces in the 3D room model and hence the simulated lighting.

According to an embodiment, the method further comprises visualizing the computed 3D room model at a user interface of the user device. Alternatively or additionally, a 2D slice and/or a 2D floorplan may be derived from the 3D room model and visualized at the user interface. As mentioned hereinabove, also other information, for example related to the at least one lighting measure, to the simulation of the lighting, to the lighting specification, and/or to the determination whether the lighting specification is met by the simulated lighting may be visualized at the user interface.

The 3D room model, the 2D slice, and/or 2D floorplan may also be navigated by the user at the user interface, and/or it may be adjusted based on providing one or more user inputs at the user interface of the user device. Therein, the user interface may combine visualization and user input means, e.g. in the form of a touch display, or separate means for visualization and user input may be provided.

According to an embodiment, the method further comprises adjusting the 3D room model based on one or more user inputs at the user device, and re-simulating the lighting in the at least part of the room using the adjusted 3D room model and/or re-computing the at least one lighting measure. For instance, the user may replace one or more surfaces or surface materials, and the lighting measure may be re-calculated. Alternatively or additionally, one or more objects in the room may be replaced, adjusted, removed and/or added. For instance, one or more objects may adjusted in size and/or color. Alternatively or additionally, a wall color of one or more walls in the room may be changed. Alternatively or additionally, a floor material may be changed. Alternatively or additionally, a room geometry may be changed and/or adjusted. Alternatively or additionally, one or more light sources in the 3D room model may be changed or adjusted in terms of any parameter related to or influencing the lighting. Generally, the user may adjust the entire 3D room model or interior room according to its needs and re-calculate the lighting measure to check whether the predefined lighting specification is met in such configuration.

It is noted that re-calculation and re-simulation can be performed at the user device or at the computing device. For instance, one or more user inputs may be received at the user device, transmitted to the computing device, and the re-simulation of the lighting may be performed at the computing device. Results of the re-simulation, including the re-calculated lighting measure may then be transmitted to the user device. Alternatively or additionally, the-re-simulation may be performed at the user device.

According to an embodiment, adjusting the 3D room model includes one or more of replacing an object in the room, removing an object from the room, adding an object to the room, modifying a room geometry, modifying a color of an object, modifying a color of a surface in the room, modifying a material of a surface in the room. One or more of such adjustments may be performed automatically or in response to receiving one or more user inputs.

According to an embodiment, simulating the lighting in the at least a part of the interior room includes simulating light emission of one or more artificial light sources located in the room using one or more lighting models representative of a light emission by the one or more artificial light sources. For example, each lighting model may define one or more emission parameters, including one or more of a color temperature, a color spectrum, a dimension, a geometry, a type, a position in the room, an orientation of the artificial light source in the room, a light flux, an energy consumption, and/or a CIE flux code (CIE—Commission internationale de l'éclairage) of the associated artificial light source. One or more of such parameters may be defined for one or more lighting models of the one or more artificial light sources, which may be included in the 3D room model for the simulation of the lighting. Hence, light emission may be accurately simulated in the interior room, thereby allowing for an accurate and efficient determination or estimation of the expected lighting.

According to an embodiment, the method further comprises detecting, based on the scanning data, one or more light sources located in the room, and removing at least a part of the detected one or more light sources in the computed 3D room model. The removed at least part of the light sources may optionally be replaced by one or more artificial light sources, for example as selected by the user. In particular, all detected light sources may be removed, which may allow a user to replace all light sources in the room.

For instance, a user may define one or more emission parameters of one or more artificial light sources, which may be placed at one or more positions in the room. Optionally, a pre-selection or recommendation of artificial light sources may be provided to the user. For instance, a recommendation for an artificial light source may be determined by the user device and/or computing device based on the 3D room model and based on the predefined lighting specification. The user may then optionally select such recommendation at the user interface, and further optionally adjust or alter one or more emission parameters of the one or more artificial light sources, which may include positioning of the corresponding artificial light source in the room.

According to an embodiment, the method further comprises including, in the 3D room model, one or more lighting models representative of a light emission by one or more artificial light sources. The method may optionally comprise adjusting one or more emission parameters of the one or more lighting models, such that the simulated lighting in the at least part of the room meets the predefined lighting specification. For instance, one or more of a color temperature, a color spectrum, a dimension, a geometry, a type, a position in the room, an orientation of the artificial light source in the room, a light flux, an energy consumption, and/or a CIE flux code of the associated artificial light source may be varied and/or adjusted. Alternatively or additionally, at least one of a number, geometry and a position of the artificial light sources in the room may be adjusted, such that the simulated lighting in the at least part of the room meets the predefined lighting specification. Such adjustment may be performed automatically at the user device and/or computing device in order to ensure that the predefined lighting specification can be fulfilled.

Optionally, one or more lighting models associated with one or more artificial light sources may be adjusted based on a user input. For instance, the user input may be indicative of one or more of a product name, a manufacturer, an ID, at least one emission parameter for at least one artificial light source, one or more lighting criteria, and a lighting specification. Based on one or more of such inputs, the user device and/or computing device may determine one or more artificial light sources and include the corresponding lighting models in the 3D room model for simulating the lighting.

According to an embodiment, the lighting specification includes a first lighting criterion indicative of a light intensity threshold and a second lighting criterion indicative of a threshold for an energy consumption of the one or more artificial light sources, wherein a first lighting measure indicative of the light intensity and a second lighting measure indicative of the energy consumption are determined based on simulating the lighting in the at least part of the room. Further, the method comprises modifying and/or adjusting at least one lighting model representative of light emission by one or more artificial light sources in the room, such that the first lighting measure meets the light intensity threshold indicated by first lighting criterion and such that the second lighting measure meets the threshold for the energy consumption indicated by the second lighting criterion. Accordingly, each of the first and second lighting criteria may be considered a target in the lighting planning, and one or more lighting models of one or more artificial light sources may be adjusted such that both criteria or targets are met. Hence, manifold criteria can be applied in the lighting planning and an optimum solution meeting various criteria may efficiently be determined. It should be noted that also more than two lighting criteria can be included in the lighting specification and considered in the lighting planning. Also, this approach allows for an optimum trade-off between different lighting criteria, such as an optimum trade-off between light intensity and energy consumption.

According to an embodiment, the method further comprises modifying and/or adjusting at least one lighting model representative of one or more artificial light sources in the room, such that energy consumption of the one or more artificial light sources is minimized. This can include adjusting one or more emission parameters of one or more lighting models. Alternatively or additionally, a number, position in the room, type or other parameter of one or more artificial light sources may be adjusted. Accordingly, the lighting planning may be optimized in terms of minimizing energy consumption.

According to an embodiment, determining the at least one lighting measure includes determining an energy consumption of one or more artificial light sources in the room. The energy consumption may be estimated based on simulating the lighting, for example taking one or more emission parameters and/or characteristics of the one or more artificial light sources into consideration. An energy consumption, for example, be determined as amount of electrical energy expectedly used for the lighting per time.

According to an embodiment, simulating the lighting in the at least part of the interior room includes computing, for one or more points in the at least part of the room, one or more point measures related to at least one of a light intensity, a color temperature, and a light spectrum of light emitted by the one or more artificial light sources, in order to determine the at least one lighting measure. Accordingly, the lighting measure may be determined as point measure associated with a particular point or position in the room, which may be given in two or three-dimensional spatial coordinates.

According to an embodiment, a plurality of point measures related to at least one of a light intensity, a color temperature, and a light spectrum of light emitted by the one or more artificial light sources is determined for a plurality of different points in the room. Further, the method may comprise aggregating at least a subset of the determined point measures to determine one or more region measures related to at least one of a light intensity, a color temperature, and a light spectrum of light emitted by the one or more artificial light sources. For instance, a region measure may be determined for a homogenous surface in the room. By aggregating the point measures, the computing burden may be reduced, without decreasing accuracy of the simulation of the lighting. Further, a region measure may define or constitute the at least one lighting measure. In other words, the at least one lighting measure may be determined as region measure.

In an example, aggregating the plurality of point measures may include one or more of computing an average value, a mean value, a maximum value and a minimum value of the subset of point measures. For instance, a subset of point measures may be determined which may only differ or be identical within a predefined range or percentage. Said subset of point measures may indicate a homogenous surface, and hence may be aggregated to determine the region measure and/or the at least one lighting measure. Such approach may also allow to restrict the evaluation of the lighting measure with respect to the lighting specification to a particular surface in the room.

For example, the lighting specification may define a minimum light intensity desired at a workbench, worktop or office table, and the region measure for the workbench, worktop or office table may be computed by simulating the lighting and comparing it as lighting measure with the minimum light intensity specified by the lighting specification. Hence, the evaluation may be limited to the part of interest in the room, while the lighting in other room areas may not be considered or may be evaluated against a different lighting specification.

According to an embodiment, point measures associated with a surface of an object in the room and/or arranged in a plane in the room are aggregated. Hence, a region measure may be determined for a particular surface or the entire surface of an object. The region measure associated with the surface of the object may then be used as lighting measure and evaluated against the predefined lighting specification. Again, this allows to increase overall versatility of the lighting planning, because the lighting specification can either be limited to specific objects or different lighting specifications can be applied to different objects.

According to an embodiment, point measures associated with a particular room area are aggregated to generate the at least one region measure. Alternatively or additionally, point measures arranged in a predefined area or volume of the room are aggregated to generate the at least one region measure. For instance, a first region measure may be computed for a first room area and a second region measure may be computed for a second room area different than the first room area. The first region measure may constitute a first lighting measure that can be evaluated against a first predefined lighting specification. Alternatively or additionally, the second region measure may constitute a second lighting measure that can be evaluated against a second predefined lighting specification, which may differ from the first lighting specification. For each of the first and second lighting measures it may be determined whether the corresponding lighting specification is met. Hence, an area-specific lighting planning may be provided, which may allow to take different lighting criteria for different room areas into account, for example in accordance with an intended use of the various room areas.

According to an embodiment, the method further comprises visualizing one or more point measures and/or one or more region measures at a user interface of the user device based on an overlay in the 3D room model or in a 2D slice of the 3D room model. For example, a color overlay where colors may be associated with particular values of the point and/or region measures, may be included in the 3D room model or a 2D slice thereof.

According to an embodiment, the method further comprises calculating at least one confidence value based on reconstructing at least a part of a homogenous surface in the room using the 3D room model. Further, the method may comprise utilizing the calculated confidence value as margin in the simulation of the lighting of the at least part of the room to reflect an uncertainty of an estimation of a material property of the at least part of the homogenous surface in the room.

According to an embodiment, the at least one confidence value is calculated based on reconstructing a material property of the at least part of the homogenous surface, in particular based on computing a mean and a standard deviation of the reconstructed material property.

For example, the reconstruction of the (e.g. homogenous) surface may include determining a surface material at a plurality of points on the surface, for example based on estimating one or more of a bidirectional reflectance function, a bidirectional texture function, a light reflectance value, an RGB reflectance vector, and a multi-spectral reflectance vector. The mean and standard deviation of the distribution of determined surface materials may then be used in the simulation of the lighting or forwarded to the simulation stage, wherein the inverse of the standard deviation may be used as confidence value or margin for the estimated surface material in the simulation of the lighting. Hence, efficiency and accuracy of the lighting planning can be improved.

According to an embodiment, simulating the lighting comprises representing a material of a surface in the room based on assigning one or more of a bidirectional reflectance function, a bidirectional texture function, a light reflectance value, an RGB reflectance vector, a multi-spectral reflectance vector, and a physically based rendering material model to one or more of a single point, a region, a surface and an object in the room. In other words, a surface of the room and/or an object in the room may be represented in the 3D room model based on one or more of a bidirectional reflectance function, a bidirectional texture function, a light reflectance value, an RGB reflectance vector, a multi-spectral reflectance vector, and a physically based rendering material model. Generally, this may allow to take the surface properties potentially affecting the lighting in the room into consideration in the simulation.

According to an embodiment, the method further comprises computing a mean reflectance value for the region, the surface and/or the object in the room and assigning the mean reflectance value to the region, the surface and/or the object. Hence, computing burden may be reduced, which may increase overall efficiency of the lighting planning.

According to an embodiment, the method further comprises determining an intended use of the at least part of the room based on a user input specifying the intended use, and selecting the predefined lighting specification in accordance with the intended use of the at least part of the room. For example, a room type, such as kitchen, office or bedroom may be defined by the user, which may be associated with a particular intended use that can be used by the user device and/or computing device to select a corresponding lighting specification. For instance, a set of different lighting specifications for different room types and/or intended uses may be stored in a database at the user device and/or computing device, and one or more of the lighting specifications may be selected based on one or more suer inputs. For example, one or more lighting specifications may be selected by the user and/or may be selected based on receiving a user input.

According to an embodiment, the method further comprises obtaining further scanning data indicative of one or more scans of at least a part of the interior room with newly installed light sources, re-computing the 3D room model using the further scanning data, and re-computing the at least one lighting measure to determine correct placement and installation of the newly installed light sources in the room. Accordingly, correct installation and placement of light sources in the room can be checked based on re-scanning the room. Also deviations with respect to previous conditions may be determined and optionally visualized at the user device.

According to an embodiment, the method further comprises rendering a scene of the room, including results of the simulated lighting, and visualizing the rendered scene at the user interface. Therein, the rendered and/or visualized scene may correspond to graphical representation of the simulated lighting. The rendered scene may further include the 3D room model, a 2D slice thereof, a 2D floorplan derived therefrom or other information. This may allow to provide a realistic impression about the expected lighting in the interior room.

Optionally, rendering the scene may include generating scene data indicative of the scene. For example, scene data may be generated at the user device and/or the computing device. In other words, the scene can be rendered at the user device and/or at a computing device remote from the user device.

According to an embodiment, the method further comprises simulating daylight penetrating trough one or more windows in the room and including the simulated daylight in the rendered scene of the room. Hence, daylight can be taken into account in the overall lighting planning, which can include daylight during one or more particular day and/or night times, such as in the evening, at noon, during night, at dawn, at dusk or other times, which may optionally be user definable. For instance, the effect of daylight on the lighting may be investigated by the user by applying different daylight conditions to the simulated lighting.

According to an embodiment, the method further comprises adjusting the lighting in the rendered scene based on one or more user inputs related to actuating a light source located in the room. For instance, in accordance with or upon receiving the user input, an artificial light source in the 3D room model and associated with the actuated light source may be actuated. Hence, the user may investigate the effect of actuating, i.e. switching on or off, one or more light sources. Also the effect on the evaluation of the at least one lighting measure against the lighting specification may be investigated.

According to an embodiment, the method further comprises providing a lighting plan defining one or more light sources at one or more positions in the room. For instance, a lighting plan may include one or more lighting models for one or more light sources, which have been simulated as one or more artificial light sources and found to result in simulated lighting that meets the predefined lighting specification, as described hereinabove.

According to an embodiment, the method may comprise generating one or more recommendations for one or more lighting plans, and providing the one or more recommendations to the user device. Therein, a recommendation of a lighting plan may include a recommendation for one or more (artificial) light sources. For instance, a recommendation for a lighting plan and/or one or more light sources may be determined by the user device and/or the computing device based on the 3D room model and the simulated lighting, such that the lighting specification is expectedly fulfilled when the one or more light sources are installed.

For instance, a light plan with one or more lighting models or corresponding light configuration or arrangement of light sources in the room can be suggested based on heuristics including one or more of the following, room geometry, windows, doors, objects in the room (e.g. desks, couches, tv), materials in the room, intended use of the room, user characteristics (e.g. age, height) or others.

Optionally, a recommendation for a light plan can be based on previously planned rooms showing similarity to the current room. Similarity criteria can refer to one or more of the following, geometry, windows, doors, objects in the room, materials, intended use, user characteristics or others. A similar room can be obtained by means of a nearest neighbor search based on selected criteria. A configuration from a similar room can be directly translated to a new room after registration. Based on heuristics, also adjustments are possible.

Light source configurations and/or recommendations for one or more lighting plans can also be suggested based on learning-based methods (machine learning, deep learning). Based on a set of input parameters, such as geometry, windows, doors, objects in the room, materials, intended use, user characteristics and a training data set, a model can be optimized with respect to a certain measure.

Further optionally, the current status-quo in a room can be assessed (based on the detected existing lightings) and additional lightings can be recommended to improve illumination or lighting quality of a room.

According to an embodiment, the scanning data is processed at a time and/or location different than a time and/or location, at which the scanning data was acquired. For instance, the scanning data may be acquired at a first time and/or first location, and the scanning data may be processed, e.g. for computing the 3D room model and/or the at least one lighting measure, at a second time and/or a second location. Therein, the first time may be different than the second time. Alternatively or additionally, the first location may be different than the second location. For instance, the scanning data may be acquired at the user device and transmitted for further processing to a computing device located remote from the user device.

A further aspect of the present disclosure relates to a computing device configured to perform steps of the method for lighting planning, as described hereinabove and hereinbelow. Any disclosure presented herein with reference to the method equally applies to the computing device.

The computing device may be embodied as user device, in particular as mobile user device, such as a smartphone, smart device, tablet or notebook. Alternatively or additionally, the computing device may be embodied as cloud computing device, such as a cloud server, a server or the like. Alternatively or additionally, the computing device may be embodied as an arrangement or system comprising a user device and a further computing device communicatively coupled to the user device. Accordingly, the computing device may refer to the user device, to the computing device communicatively couplable thereto, or to an arrangement or system including both the user device and the computing device communicatively couplable thereto.

A further aspect of the present disclosure relates to a computer program, which, when executed on a computing device, instructs the computing device to carry out steps of the method for lighting planning, as described hereinabove and hereinbelow.

A further aspect of the present disclosure relates to a computer-readable medium having stored thereon a computer program, which, when executed on a computing device, instructs the computing device to carry out steps of the method for lighting planning, as described hereinabove and hereinbelow.

These and other aspects of the disclosure will be apparent from and elucidated with reference to the appended figures, which may represent exemplary embodiments.

### BRIEF DESCRIPTION OF THE DRAWINGS

The subject-matter of the present disclosure will be explained in more detail in the following with reference to exemplary embodiments which are illustrated in the attached drawings, wherein:

FIG. 1 shows a computing system for lighting planning of an interior room according to an exemplary embodiment;

FIG. 2 shows a flowchart illustrating steps of a method for lighting planning of an interior room according to an exemplary embodiment; and

FIG. 3 illustrates steps of a method for lighting planning of an interior room according to an exemplary embodiment.

The figures are schematic only and not true to scale. In principle, identical or like parts are provided with identical or like reference symbols in the figures.

### DETAILED DESCRIPTION OF EXEMPLARY EMBODIMENTS

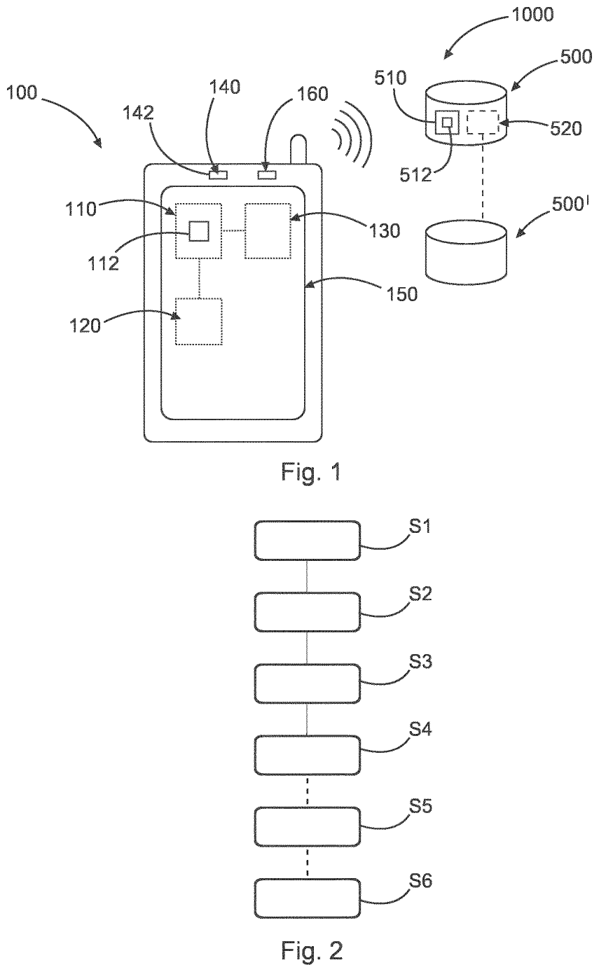

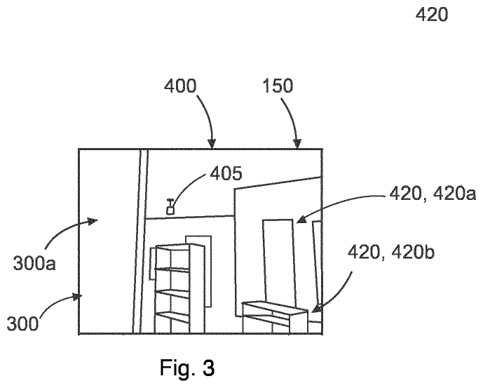

FIG. 1 shows a computing system 1000 for lighting planning of an interior room according to an exemplary embodiment. The computing system 1000 of FIG. 1 can particularly be configured to carry steps of the method for lighting planning described hereinabove and/or for example described with reference to one or both FIGS. 2 and 3.

The computing system 1000 includes a user device 100 and cloud computing devices 500, 500′ or servers 500, 500′ communicatively coupled thereto to indicate a cloud computing networks. Only a single computing device 500, 500′ or more than two may be used instead.

It is noted that any or all of the steps of the method for lighting planning, for example as described hereinabove or hereinbelow with respect to FIGS. 2 and 3, can be performed at the user device 100, the one or more computing devices 500, 500′ or both, i.e. the computing system 1000. Also, it is noted that the computing system 1000 can also be referred to as computing device herein for reasons of simplicity.

The user device 100 comprises a processing circuitry 110 with one or more processors 112 for data processing. The user device 100 further includes a data storage 120, for example for storing software or computer instructions instructing the user device 100 to perform one or more steps, operations or functions, as described herein.

The user device 100 of FIG. 1 is exemplary illustrated as smartphone or mobile device. The present disclosure, however, is not limited in this respect.

The user device 100 further comprises a user interface 150 for displaying data and/or receiving one or more user inputs from a user of the user device 100.

The user device 140 further comprises at least one sensor 140 configured to acquire sensor data and/or scanning data of one or more scans of the room. The senor 140 may include one or more image sensors for acquiring image sensor data or image data indicative of one or more images of room. The image sensor 140 may be part of a camera 142 and/or other means for acquiring one or more images and/or corresponding sensor data. The at least one image sensor 140 may refer to or include any one or more of an RGB sensor, a multispectral sensor, or other type of image sensor.

The user device 100 optionally comprises one or more further sensors 160, such as a LIDAR senor, a gyroscope, an accelerometer, an acoustic sensor, a depth sensor, a stereo camera, or any other sensor 160, which may be configured to acquire further sensor data that may optionally be used for modeling and/or reconstructing an interior room, and/or for lighting planning.

The sensor data of the at least one image sensor 140 and/or the further sensor data of the at least one further sensor 160 may optionally be stored in the data storage 120.

Moreover, the user device 100 includes a communication circuitry 150 for communicatively coupling the user device 100 to one or more servers 500, 500′ or computing devices 500, 500′ of the computing system 1000. The communication circuitry 150 of the user device 100 may be configured for wired and/or wireless communication with one or more other computing devices, as exemplary indicated by the servers 500, 500′ in FIG. 1.

In particular, FIG. 1 schematically shows a server 500 with a processing circuitry 510 and one or more processors 512 for data processing. The server 500 is particularly configured to receive sensor data, point cloud data and/or other data from the user device 100 for modeling and/or reconstructing an interior room.

The server 500 may refer to a plurality of computing devices, for example a plurality of interoperating servers 500 of a cloud computing network, as indicated by the additional computing device or server 500′ in FIG. 1.

Further, server 500 may include one or more modules, engines and/or dedicated functional blocks 520 for performing one or more dedicated tasks or operations in the process of modeling and/or reconstructing the interior room and/or for lighting planning, as exemplary described with reference to FIGS. 2 and 3. In particular, one or more Al-based engines, modules, algorithms and/or circuitries 520 may be implemented in hard- and/or software for performing one or more of the operations and functionalities described herein.

For example, the server 500 may include one or more dedicated blocks, modules and/or engines 520 for reconstruction of a room and/or one or more objects. Alternatively or additionally, the server 500 may include one or more dedicated blocks, modules and/or engines 520 for retrieval of data from a database for reconstruction and/or visualization and/or modeling of a room. Alternatively or additionally, the server 500 may include one or more dedicated blocks, modules and/or engines 520 for simulating the lighting in the room.

The computing system 1000, i.e. one or both the user device 100 and the one or more servers 500, 500′ may be utilized to perform steps of a method for lighting planning of an interior room (400, see FIG. 3).

FIG. 2 shows a flowchart illustrating steps of such method for lighting planning of an interior room (400, see FIG. 3) according to an exemplary embodiment.

In a first step S1, scanning data indicative of one or more scans of at least a part of the interior room 400 performed with a user device 100, for example as shown in FIG. 1 are obtained. The scanning data may be obtained at the user device 100 and/or at the computing device 500, 500′ or server 500, 500′.

Optionally, step S1 may include performing a scan with the user device 100, for example based on moving the user device 100 along a trajectory with two or more different positions in the room to acquire sensor data using the sensor 140 and/or further sensor 160 to generate the scanning data. For instance, the scanning data may refer to or include a point cloud and/or point cloud data. Optionally, several point clouds or point cloud data can be aggregated to generate the scanning data.

Step S1 can further optionally include one or more of transmitting the scanning data from the user device 100 to the computing device or server 500, 500′.

In a further step S2, based on the scanning data, a 3D room model indicative of a 3D geometry of the interior room 400 and at least one of a surface material 300a (see FIG. 3) of a surface 300 (see FIG. 3) and an object 420 (see FIG. 3) located in the room 400 is computed, for example at the user device 100 and/or the computing device or server 500, 500′.

In a further step S3, at least one lighting measure indicative of a lighting characteristic in at least a part of the room 400 may be computed based on the 3D room model and based on simulating a lighting generated by one or more artificial light sources 405 (see FIG. 3) located within the room 400. Also step S3 may be performed at the user device 100 and/or at the computing device or server 500, 500′.

In a further step S4, it is determined, based on the computed at least one lighting measure, whether the simulated lighting in the at least part of the room meets a predefined lighting specification indicative of a quality of the lighting in the at least part of the room.

As described in more detail hereinabove and hereinbelow, the at least one lighting measure may be indicative of one or more of a light intensity, a light distribution, a homogeneity of the lighting, a color of the lighting, a color spectrum of the lighting, a color temperature of the lighting an energy consumption of the one or more artificial light sources 405 (see FIG. 3), and a degree of comfort on an individual in the room resulting from the lighting. Alternatively or additionally, the predefined lighting specification may be defined by one or more lighting criteria indicative of one or more of a light intensity threshold, a minimum light intensity, a maximum light intensity, a predefined light distribution, a threshold for a homogeneity of the lighting, a predefined color of the lighting, a predefined color spectrum of the lighting, a predefined color temperature of the lighting, a threshold for an energy consumption of the one or more artificial light sources, and a predefined degree of comfort on an individual in the room resulting from the lighting.

Optionally, determining whether the simulated lighting in the at least part of the room meets the predefined lighting specification in step S4 may include comparing the at least one lighting measure to one or more lighting criteria associated with the predefined lighting specification. Further optionally, a conclusion as to whether the at least one lighting measure meets one or more lighting criteria associated with the predefined lighting specification may be generated. Corresponding information may also be provided to the user device 100 and/or shown or visualized at a user interface 150 thereof.

In an optional step S5, the determined 3D room model, a 2D slice thereof and/or the simulated lighting may be visualized at the user interface 150 of the user device. For instance, a corresponding scene may be rendered at the computing device 500, 500′ and/or at the user device 100.

FIG. 3 exemplary shows a scene visualized or rendered at the user interface 150 of the user device 100 in optional step S5 of FIG. 2.

As indicated in FIG. 3 and described in detail hereinabove, computing the 3D room model in step S2 may include determining based on the scanning data a room geometry and optionally representing or reconstructing the room geometry by one or more base elements, as described in more detail hereinabove.

Optionally, one or more objects 420, such as one or more windows 420a or doors and/or items of furniture 420b may be detected based on analyzing the scanning data and included in the 3D room model. For instance, object data may be retrieved from a database for this purpose, as described in more detail hereinabove

Alternatively or additionally, one or more surfaces 300 and/or surface materials 300a may be determined based on analysing the scanning data and included in the 3D room model, e.g. by assigning one or more of a bidirectional reflectance function, a bidirectional texture function, a light reflectance value, an RGB reflectance vector, a multi-spectral reflectance vector, and a physically based rendering material model to one or more of a single point, a region, a surface and an object in the room 400.

Further optionally, alighting model for one or more artificial light sources 405, as shown in FIG. 3, may be included in the 3D room model and optionally visualized at the user interface 150 of the user device 100. Therein, the lighting model may define one or more emission parameters, including a color temperature, a color spectrum, a dimension, a geometry, a type, a position, a light flux, an energy consumption, and/or a CIE flux code of the associated artificial light source 405.

In a further optional step S6, information related to the computed at least lighting measure and or related to a comparison of the at least one lighting measure to one or more lighting criteria associated with the predefined lighting specification may be provided and/or displayed at the user interface 150 of the user device 100.

Further additional, alternative or supplemental steps, as described hereinabove and also described in the following, may be performed.

In the following various exemplary aspects of the computer-implemented method for lighting planning of an interior room 400 are summarized.

The computer implemented method for illumination and/or lighting planning can include scanning a room with a mobile device or user device 100, computing a 3D room model, including 3D geometry, one or more surface materials 300a of one or more surface 300 and one or more objects 420, 420a, 420b arranged in the room 400 based on the scanning data. The method may optionally include visualizing the 3D room model at the user interface 150 of the user device 100, thereby potentially allowing the user to apply modifications to the 3D room model. Further, the method may comprise performing lighting simulation in the 3D room model, and optionally providing the user with information about one or more computed lighting measures in the room 400. Further optionally, the 3D room model may be visualized, for example along with the computed one or more lighting measures and/or along with information related to the evaluation, for example showing a result of the evaluation, of the one or more lighting measures with respect to the predefined lighting specification.

As an example, a calculation of a lighting measure can be conducted to determine whether the lighting meets a lighting criterion defined in the lighting specification, such as a minimum light intensity as e.g. defined in DIN EN 12464-1:2021, or whether the lighting does not meet the lighting standard or criterion. Other criteria that can be considered in the lighting specification and/or determined based on simulating the lighting in the room 400 can correspond to comfort of inhabitants or individuals, which can be measured based on a continuous variable. During computation, also factors such as human mood can be included. The computer implemented method may further include producing a conclusion as to whether the computed one or more lighting measures meet the one or more lighting criteria defined in the lighting specification. Hence, a suitability of the lighting for the room may be evaluated or estimated.

As mentioned hereinabove, adequate lighting may be important or even imperative for human beings in professional and private life. Right illuminance may not only be relevant to fulfill visual tasks, but may also exhibit a relevant comfort factor. Particularly in professional environments, lighting may even be subject to regulatory requirements. For offices, for example, standards may be defined determining the required minimum illumination or light intensity in certain room areas (e.g. § § 21, 22 Arbeitnehmerlnnenschutzgesetz (ASchG), ISO 9241-6). Energy efficiency can be a further target. The goal can be to achieve standards or optimum human comfort in a room with minimum energy consumption.

Any one or more of such aspects or criteria can be included in the lighting specification. Corresponding lighting measures can be determined based on simulating the lighting in the room 400 using the computed 3D room model, thereby allowing to determine whether or not the simulated lighting meets the one or more lighting criteria of the lighting specification.

By means of the user device 100, an automated scanning and processing may be provided at the user device 100. Automated scanning may have the potential to capture all relevant aspects of an indoor room 400 within a few seconds and include corresponding information in the scanning data, e.g. a point cloud of the room 400. Some user devices 100 may also be provided with highly resolved cameras showing a high image quality and the potential to capture multiple temporal frames. Also depth sensors (e.g. LiDAR sensors) may be provided at certain user devices 100, which further improve the process of 3D reconstruction and computation of the 3D room model. 3D reconstruction in this context may refer to the reconstruction of a parametric 3D model for the room, e.g. consisting of a small number of base elements. A plane wall 300 of the room, for example, can be modeled by a polygon (mostly a rectangle) on a plane. This parametric representation may allow simple modifications of the model as well as efficient further processing. Based on one or more captured frames or scanning data (each frame or scanning data e.g. containing one or more of the following: grayscale image, RGB image, multispectral image, depth image), the 3D room model containing the 3D geometry of the room 400 can be reconstructed by means of classical image processing techniques, such as photogrammetry or by means of data driven approaches, such as deep learning. In addition to the room geometry, objects 420, 420a, 420b, such as e.g. items of furniture 420b, windows 420a, doors, lighting sources 405, can be detected and optionally corresponding object data may be retrieved from a dataset or database and included in the 3D room model. In addition, surface materials 300 a of one or more surfaces 300 can be estimated and also included in the 3D room model. Finally, all relevant information is included in a digital twin to generate the 3D room model, as for example illustrated in FIG. 3.

Based on the computed 3D room model, the user may obtain a visualization including room geometry, the relevant objects 420, 420a, 420b, and the surface materials 300a of one or more surfaces 300. The user can optionally, remove, add, replace, and/or modify existing room assets or objects. E.g. detected furniture can be removed, geometry can be adjusted and surface materials can be changed. Adjustments could be either needed due to errors in the automated scanning and reconstruction process or due to intended changes performed by the user (e.g. due to renovation).

For example, if the user aims to paint a room 400 with a different color, the effect on the illumination or lighting can be directly measured and visualized at the user interface 150. For lighting planning, all detected light sources can be removed and new light sources or artificial light sources 405 may be installed in the 3D room model, e.g. by selecting them from a dataset or database. It is also an option to retrieve models for detected lightings, such as particular lighting models, from a database, to use the models during the computation or simulation of the lighting. This could be relevant if additional light sources should be installed besides the existing ones. For the lighting models, parameters influencing the light emission, such as color temperature, dimensions/geometry, type, light flux, and the CIE flux code, and others may be defined in the corresponding lighting model.

Based on the acquired or computed 3D room model, e.g. including one or more lighting models for one or more artificial light sources 405, illumination or lighting simulation may be performed. Based on one or more simulation models modeling the physics, for each point or position within the room, one or more measures (in the following “point measures”) can be determined. A measure can be e.g. the light intensity (scalar), or the color temperature (scalar) or a vector providing the full spectrum of emitting light. Based on one or more point measures in a room, an aggregation can be performed providing a single or a plurality of measures representing a region (in the following “region measures”). Based on the determined one or more point measures and/or region measures, the one or more lighting measures may be computed.

For example, in a particular part of a room, e.g. the height of working desks, which could be represented by a plane inside the room, can be modeled to compute point measures in these regions. The aggregation could be, in the simplest form an average, a minimum or a maximum light intensity of the simulated light. Aggregation could also be performed in room areas. For example, all point measures in a certain radius around one or more reference points or positions can be collected to generate a region measure.

All or any of the results of the simulation and/or comparison of the lighting measures with the lighting specification can be presented to the user via statistics or visualized to the user. Single region measures or corresponding lighting measures can be provided to the user as numerical output. Point measures or region measures not corresponding to the complete room can also be presented, e.g. by means of color overlays in the 3D room model or in a 2D slice of the room model.

In general, the proposed technique or method for lighting planning may allow the incorporation of a plurality of parameters affecting or influencing the lighting in a room, in turn increasing the estimation accuracy, efficiency and flexibility of lighting planning systems. After a computation of the 3D room model, the user can easily perform adjustments to the model and rerun the computation or lighting simulation. Since the whole process of lighting planning may be performed automatically with the same system 1000, user device 100 and/or computing device 500, 500′, confidences of the reconstruction approach can be forwarded to the simulation stage. A confidence value can be obtained for example by reconstructing material properties based on e.g. different patches of a homogeneous wall or floor, followed by a computation of a mean and a standard deviation. The inverse standard deviation can be used as confidence value. E.g. if material estimation shows a low confidence (corresponding to a high expected error), this uncertainty can be forwarded to the simulation stage. This allows to provide confidence values for the illuminance estimation or lighting simulation and optionally inform the user about expected variations. Based on an additional scan process providing further scanning data, also a retrospective check can be performed to assess whether the light sources have been mounted according to a lighting plan, in turn providing another confidence measure for the computed measures. Depending on the confidence measures, a higher or lower margin can be applied to ensure that the requirements are met with a high probability, e.g. independent of the confidence values.

For representing a surface material for light simulation, several approaches can be applied. Besides complex representations of material properties such as bidirectional reflectance functions (BRDFs) and bidirectional texture functions (BTFs), simplified approaches, such as physically based rendering (PBR) material models can be used as well. Depending on the final goal, also even more simplified methods relying on single reflectance values (light reflectance value (LRV)) or representations based on RGB or multi-spectral reflectance vectors can be applied. A reflectance function or value can be assigned either to a single pixel or to a semantic object 420, 420a, 420b, 300 in the scene or 3D room model. In the latter case, e.g. a wall or floor segment or other object arranged in the room 400, can be assigned with a single reflectance. In the case of textured or multi-colored segments, the computation of a mean reflectance can be performed.

Besides items of furniture, doors, windows, surfaces 420, 420a, 420b, 300 and surface materials 300a also light sources can be detected based on the scanning data. Also, a lighting model can be retrieved from a database containing one or more light emission parameters. The retrieved one or more lighting models can be used to allow a simulation of the existing setting and compare with one or more new settings. It additionally allows the addition of novel light sources besides existing ones. Since the retrieval can be challenging, a manual adjustment of the detected light source(s) is possible. Based on one or more of the following, product name, manufacturer, id, light parameters the user can provide details on the light sources to increase accuracy of the simulation model or lighting model(s). Since there is a vast number of different light sources, instead of a retrieval of the lighting models, single relevant parameters, particularly characterizing the emission of light, can be estimated based on regression models.

Based on the computed 3D room model, the user can obtain a visualization including room geometry, the relevant objects 420, 420a, 420b, the surfaces 300, and the surface materials 300a, for example as shown in FIG. 3. The user can now inspect the room 400, apply different views, interact with the room 400, inspect the surface materials 300a (e.g. of walls, floors) and so forth.

The user can optionally remove, replace, add and/or modify existing room assets. E.g. detected items of furniture 420b can be removed, new furniture items can be added, furniture items can be moved, geometry can be adjusted, and/or surface materials can be changed. Adjustments could be either needed due to errors in the automated scanning and reconstruction process or due to intended changes performed by the user. The user could be interested to change the room characteristics in order to simulate a new room after renovation or to investigate the lighting situation in case of changed settings. Thereby the room layout can be optimized effectively based on simulation. For example, if the user aims to paint a room 400 with a different color, the effect of the illumination can be directly measured and visualized. Similarly, the impact of novel furniture items 420b can be assessed time- and cost-efficiently.

For lighting planning, for example all detected light sources may be removed in the computed 3D room model and new light sources may be installed in the room by including one or more lighting models in the 3D room model, e.g. based on a user input. However, it is also an option to retrieve lighting models for detected lightings or light sources from a database, and to use the lighting models during the simulation of the lighting. This could be wanted if additional light sources should be installed besides existing ones.

The user can also be presented with a realistic rendering of the scene at the user interface, which may include a representation of the 3D room model and the simulated lighting. Parameters can be adjusted to also simulate the effect of daylight (e.g. penetrating through one or more windows 420a), switching individual lightings on and off, and dimming one or more light sources. The 3D room model can be adjusted in order to simulate different daytime, yeartime and changing weather conditions. For that purpose, also the geolocation and orientation of the user device 100 can be accessed. Rendering can be performed in real time on the user device 100 with a little loss of accuracy. To obtain optimum quality of individual frames, several strategies can be considered, such as cloud rendering, or rendering with progressive quality (e.g. if the scene is not moved for a certain amount of time, a high-quality rendering can be provided for this view).

The lighting planning described herein can be applied to various use cases. For instance, a 3D room models can be generated based on scanning a room 400. Based on computing the 3D room model, non-relevant objects can be removed. This could be detected light sources which will be removed or objects of furniture which will be removed. Also, other adjustments such as painting walls can be performed virtually in the room model. One or more (additional) light sources can be installed virtually in the 3D room model. Based on the adjusted data, a light simulation can be performed and the one or more lighting measures can be computed and optionally presented to the user. The procedure can be repeated several times until the user's requirements, e.g. as defined or reflected in the predefined lighting specification, are met or an optimum lighting measure, e.g. a maximum light intensity and/or minimum energy consumption, is obtained.

Therein, targets in light planning can be manifold. Such targets can be reflected in one or more lighting criteria defined in the lighting specification. For instance, regulatory standards (e.g. ISO 9241-6) corresponding to a minimum illumination or light intensity in certain office areas can be included in the lighting specification. However, many more application scenarios are possible, such as a light planning based on human mood as the target parameter. The user can, e.g. depending on the intended use of the room (or a part of the room) and individual preferences, adjust the intended lighting mood of a room. Lighting moods can also be suggested based on information on the room usage. For example, if a room is intended to be used as kitchen, an intensive, homogeneous illumination can be suggested or defined for the worktop in the lighting specification while a pleasant warm light can be suggested or defined in the lighting specification for the dining table.

After changing light sources in the real world, an additional 3D room scan can be performed to check whether the light sources are correctly installed. For instance, position, orientation, and/or correct model of a light source may be checked. Based on the outcome, a measurement accuracy can be provided to the user. The user can also be informed about the effect of an incorrect placement on the lighting simulation.

Optionally, one or more recommendations for a lighting plan and/or one or more (artificial) light sources may be provided. For example, based on the 3D room model, recommendations for light source configurations can be performed automatically. Therein, a light source configuration, e.g. including one or more lighting models for one or more artificial light sources 405, can be suggested based on heuristics including one or more of the following, room geometry, windows, doors, objects in the room (e.g. desks, couches, tv), materials in the room, intended use of the room, and user characteristics (e.g. age, height). A light source configuration, e.g. including one or more lighting models for one or more artificial light sources 405, can also be suggested based on previously planned rooms, e.g. showing similarity to the current room. Similarity criteria can refer to one or more of the following, geometry, windows, doors, objects in the room, materials, intended use, user characteristics. A similar room can be obtained by means of a nearest neighbor search based on selected criteria. A configuration from a similar room can be directly translated to a new room after registration. Based on heuristics, also adjustments are possible.

A light source configuration, e.g. including one or more lighting models for one or more artificial light sources 405, can also be suggested based on learning-based methods, such as machine learning or deep learning. Based on a set of input parameters, such as geometry, windows, doors, objects in the room, materials, intended use, user characteristics and a training data set, a model can be optimized with respect to a certain measure.

Similarly, the current status-quo in a room can be assessed, e.g. based on the detected existing light sources, and additional (artificial) light sources can be recommended to improve illumination quality or the quality of the lighting of a room and/or in order to meet the lighting specification.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art and practicing the claimed invention, from a study of the drawings, the disclosure, and the appended claims.

In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

Furthermore, the terms first, second, third or (a), (b), (c) and the like in the description and in the claims are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

1-47. (canceled)

48. A computer-implemented method for lighting planning of an interior room, the method comprising:
obtaining scanning data indicative of one or more scans of at least a part of the interior room performed with a user device;
computing, based on the scanning data, a 3D room model indicative of a 3D geometry of the interior room and at least one of a surface material of a surface and an object located in the room;
computing, based on the 3D room model, at least one lighting measure indicative of a lighting characteristic in at least a part of the room based on simulating a lighting generated by one or more artificial light sources located within the room; and
determining, based on the at least one lighting measure, whether the simulated lighting in the at least part of the room meets a predefined lighting specification indicative of a quality of the lighting in the at least part of the room,
preferably further comprising generating a conclusion as to whether the at least one lighting measure meets one or more lighting criteria associated with the predefined lighting specification; and optionally providing information indicative of the generated conclusion at a user interface of the user device.

49. The method according to claim 48,
wherein the at least one lighting measure is indicative of one or more of a light intensity, a light distribution, a homogeneity of the lighting, a color of the lighting, a color spectrum of the lighting, a color temperature of the lighting an energy consumption of the one or more artificial light sources, and a degree of comfort on an individual in the room resulting from the lighting, and/or
wherein the predefined lighting specification is defined by one or more lighting criteria indicative of one or more of a light intensity threshold, a minimum light intensity, a maximum light intensity, a predefined light distribution, a threshold for a homogeneity of the lighting, a predefined color of the lighting, a predefined color spectrum of the lighting, a predefined color temperature of the lighting, a threshold for an energy consumption of the one or more artificial light sources, and a predefined degree of comfort on an individual in the room resulting from the lighting.

50. The method according to claim 48,
wherein computing the 3D room model indicative of the surface material comprises assigning one or more of a bidirectional reflectance function, a bidirectional texture function, a light reflectance value, an RGB reflectance vector, a multi-spectral reflectance vector, and a physically based rendering material model to one or more of a single point, a region, a surface and an object in the room, and/or
wherein the 3D room model is a parametric 3D model indicative of one or more materials of one or more surfaces in the room, one or more light sources, one or more windows, one or more doors, one or more walls, one or more objects arranged in the room, and/or one or more items of furniture arranged in the room.

51. The method according to claim 48, further comprising:
adjusting the 3D room model based on one or more user inputs at the user device; and
re-simulating the lighting in the at least part of the room using the adjusted 3D room model and/or re-computing the at least one lighting measure,
preferably wherein adjusting the 3D room model includes one or more of replacing an object in the room, removing an object from the room, adding an object to the room, modifying a room geometry, modifying a color of an object, modifying a color of a surface in the room, modifying a material of a surface in the room.

52. The method according to claim 48,
wherein simulating the lighting in the at least a part of the interior room includes simulating light emission of one or more artificial light sources located in the room using one or more lighting models representative of a light emission by the one or more artificial light sources,
preferably wherein each lighting model defines one or more emission parameters, including a color temperature, a color spectrum, a dimension, a geometry, a type, a position, a light flux, an energy consumption, and/or a CIE flux code of the associated artificial light source.

53. The method according to claim 48, further comprising:
including, in the 3D room model, one or more lighting models representative of a light emission by one or more artificial light sources,
preferably wherein the method further comprises:
adjusting one or more emission parameters of the one or more lighting models, such that the simulated lighting in the at least part of the room meets the predefined lighting specification; and/or
adjusting at least one of a number, geometry and a position of the artificial light sources in the room, such that the simulated lighting in the at least part of the room meets the predefined lighting specification; and/or
adjusting one or more lighting models based on a user input, preferably wherein the user input is indicative of one or more of a product name, a manufacturer, an ID, at least one emission parameter for at least one artificial light source, one or more lighting criteria, and a lighting specification.

54. The method according to claim 48,
wherein the lighting specification includes a first lighting criterion indicative of a light intensity threshold and a second lighting criterion indicative of a threshold for an energy consumption of the one or more artificial light sources;
wherein a first lighting measure indicative of the light intensity and a second lighting measure indicative of the energy consumption are determined based on simulating the lighting in the at least part of the room; and
wherein the method further comprises modifying and/or adjusting at least one lighting model representative of light emission by one or more artificial light sources in the room, such that the first lighting measure meets the light intensity threshold indicated by first lighting criterion and such that the second lighting measure meets the threshold for the energy consumption indicated by the second lighting criterion.

55. The method according to claim 48,
wherein determining the at least one lighting measure includes determining an energy consumption of one or more artificial light sources in the room, and/or
wherein the method further comprises modifying and/or adjusting at least one lighting model representative of one or more artificial light sources in the room, such that energy consumption of the one or more artificial light sources is minimized.

56. The method according to claim 48, wherein simulating the lighting in the at least part of the interior room includes:
computing, for one or more points in the at least part of the room, one or more point measures related to at least one of a light intensity, a color temperature, and a light spectrum of light emitted by the one or more artificial light sources, in order to determine the at least one lighting measure,
preferably wherein a plurality of point measures is determined for a plurality of different points in the room, and wherein the method further comprises:
aggregating at least a subset of the determined point measures to determine one or more region measures related to at least one of a light intensity, a color temperature, and a light spectrum of light emitted by the one or more artificial light sources,
preferably wherein aggregating includes one or more of computing an average value, a mean value, a maximum value and a minimum value of the subset of point measures, and/or
wherein point measures associated with a surface of an object in the room and/or arranged in a plane in the room are aggregated; and/or
wherein point measures associated with a particular room area are aggregated; and/or
wherein point measures arranged in a predefined area or volume of the room are aggregated,
preferably wherein the method further comprises visualizing one or more point measures and/or one or more region measures at a user interface of the user device based on an overlay in the 3D room model or in a 2D slice of the 3D room model.

57. The method according to claim 48, further comprising:
calculating at least one confidence value based on reconstructing at least a part of a homogenous surface in the room using the 3D room model; and
utilizing the calculated confidence value as margin in the simulation of the lighting of the at least part of the room to reflect an uncertainty of an estimation of a material property of the at least part of the homogenous surface in the room,
preferably wherein the at least one confidence value is calculated based on reconstructing a material property of the at least part of the homogenous surface, in particular based on computing a mean and a standard deviation of the reconstructed material property.

58. The method according to claim 48, wherein simulating the lighting comprises representing a material of a surface in the room based on assigning one or more of bidirectional reflectance function, a bidirectional texture function, a light reflectance value, an RGB reflectance vector, a multi-spectral reflectance vector, and a physically based rendering material model to one or more of a single point, a region, a surface and an object in the room,
preferably wherein the method further comprises computing a mean reflectance value for the region, the surface and/or the object in the room and assigning the mean reflectance value to the region, the surface and/or the object.

59. The method according to claim 48, further comprising:
rendering a scene of the room, including results of the simulated lighting, preferably wherein the scene is rendered at the user device or at a computing device remote from the user device; and
visualizing the rendered scene at the user interface,
preferably wherein the method further comprises simulating daylight penetrating through one or more windows in the room and including the simulated daylight in the rendered scene of the room, and/or adjusting the lighting in the rendered scene based on one or more user inputs related to actuating a light source located in the room.

60. A computing device configured to perform steps of the method according to claim 48, preferably wherein the computing device is embodied as user device, in particular as mobile user device, as cloud computing device, or as an arrangement comprising a user device and a cloud computing device communicatively coupled to the user device.

61. A computer program, which, when executed on a computing device, instructs the computing device to carry out steps of the method according to claim 48.

62. A computer-readable medium having stored thereon a computer program according to claim 61.
